(19) United States
(12) Patent Application Publication
(10) Pub. No.: US 2014/0167083 A1
(43) Pub. Date: Jun. 19, 2014

(54) LED PACKAGE WITH INTEGRATED REFLECTIVE SHIELD ON ZENER DIODE

(71) Applicant: AVAGO TECHNOLOGIES GENERAL IP (SINGAPORE) PTE. LTD., Singapore (SG)

(72) Inventors: Chin Ewe Phang, Penang (MY); Keat Chuan Ng, Penang (MY); Lig Yi Yong, Penang (MY)

(73) Assignee: Avago Technologies General IP (Singapore) Pte. Ltd., Singapore (SG)

(21) Appl. No.: 13/720,401

(22) Filed: Dec. 19, 2012

(51) Int. Cl. H01L 23/60; H01L 33/62

(52) U.S. Cl. CPC H01L 23/60; H01L 33/62
USPC 257/98; 438/27

(57) ABSTRACT

A lighting package is disclosed. The lighting package is disclosed as including a primary light source, such as a Light Emitting Diode, and an additional electrical component that protects the primary light source from electrostatic discharge, for example. The additional electrical component may correspond to a Zener diode and may be treated with at least one material that helps reduce the light absorption of the Zener diode.

### FIELD OF THE DISCLOSURE

The present disclosure is generally directed toward light emitting devices and packages for the same.

### BACKGROUND

Light Emitting Diodes (LEDs) have many advantages over conventional light sources, such as incandescent, halogen and fluorescent lamps. These advantages include longer operating life, lower power consumption, and smaller size. Consequently, conventional light sources are increasingly being replaced with LEDs in traditional lighting applications. As an example, LEDs are currently being used in flashlights, camera flashes, traffic signal lights, automotive taillights and display devices.

Two prevalent types of LED form factors are surface-mount LEDs and thru-hole LEDs. Surface-mount LEDs are desirable for applications which require a low LED profile. Among the various packages for surface-mount LEDs, an LED package of interest is the Plastic Leaded Chip Carrier (PLCC) package. Surface mount LEDs in PLCC packages may be used, for example, in automotive interior display devices, electronic signs and signals, and electrical equipment.

Many electrical devices, such as LEDs, can be damaged when exposed to electrostatic discharge and other sources of suddenly increasing current. Zener diodes are among the most popular components used to protect electrical circuits and devices within electrical circuits from electrostatic discharge. Most Zener diodes are usually dark in color due to the material used during manufacture.

### SUMMARY

The inherently dark materials used to manufacture Zener diodes and other electrical components are known to absorb light. Specifically, when a Zener diode is mounted on the surface of a lighting package, as it often is, the Zener diode can absorb the light generated by the light source, thereby decreasing the overall light output by the lighting package. Specifically, when a Zener diode is mounted on the surface of the lighting package, the Zener diode may reduce the overall light output of the lighting package by between 3% to 5%. However, given that the Zener diode protects the light source and other electrical devices, the light losses are often tolerated.

It is, therefore, one aspect of the present disclosure to provide an improved lighting package that overcomes the above-noted shortcomings. Specifically, an electrical component is mounted on a lighting package in proximity to a light source. The electrical component may correspond to a Zener diode for example, but may correspond to any other type of device or collection of devices that are mounted onto a surface of the lighting package where such device or collection of devices are at least partially exposed to light emitted by the light source. In some embodiments, the electrical component mounted in proximity to the light source may be treated with a cover material that substantially eliminates the light losses that would otherwise occur if the light reached the electrical component. More specifically, the electrical component may be covered with a reflective or non-absorbing material. Where the electrical component corresponds to a Zener diode, the need to trade off electrostatic discharge protection with light output losses can be avoided. In other words, embodiments of the present disclosure provide the ability to maintain light output efficiencies for lighting devices without sacrificing electrostatic discharge protection for the light source and other circuits.

In some embodiments, a Zener diode provides electrostatic discharge protection for a light source mounted in proximity thereto. The Zener diode may be covered with a highly reflective cover material, thereby reducing the optical absorption inherent to the Zener diode. In some embodiments, the cover material may correspond to a white viscous paste that partially or completely covers the Zener diode after wire bonding has occurred for the Zener diode. The cover material may be applied by any number of known deposition methods such as, for example, dispensing, spraying, screen printing, etc. More specific, but non-limiting, examples of suitable cover materials include TiO2, Alumina in Epoxy, and/or a silicone adhesive material.

The present disclosure will be further understood from the drawings and the following detailed description. Although this description sets forth specific details, it is understood that certain embodiments of the invention may be practiced without these specific details. It is also understood that in some instances, well-known circuits, components and techniques have not been shown in detail in order to avoid obscuring the understanding of the invention.

### BRIEF DESCRIPTION OF THE DRAWINGS

The present disclosure is described in conjunction with the appended figures:

FIG. 1 is a top view of a lighting package in accordance with embodiments of the present disclosure;

FIG. 2A is a cross-sectional view of a first lighting package in accordance with embodiments of the present disclosure;

FIG. 2B is a cross-sectional view of a second lighting package in accordance with embodiments of the present disclosure; and

FIG. 3 is a flow chart depicting a method of manufacturing a lighting package in accordance with embodiments of the present disclosure.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

Furthermore, although the depicted lighting package 100 is a conventional C-bend PLCC, embodiments of the present disclosure are not so limited. In particular, embodiments of the present disclosure can be utilized in any type of known lighting package and/or platform. Specifically, any type of PLCC or non-PLCC package and/or platform or similar type of package for a light emitting device or collection of light emitting devices can incorporate one or more features disclosed herein. Suitable types of PLCC packages that may incorporate embodiments of the present disclosure include, without limitation, a Moonstone Package which has one or more leads protruding to its side, an L-bend PLCC, a PLCC with one or more leads protruding from its bottom, and so on. In some embodiments, the lighting package 100 may be manufactured according to the industry standard PLCC-4. Said another way, it should be appreciated that the features disclosed herein can be applied to any type of packaging method such as lighting packages having a ceramic housing, a metal housing, no housing (e.g., a PCB without a housing), or any other lighting package that utilizes a circuit protection components.

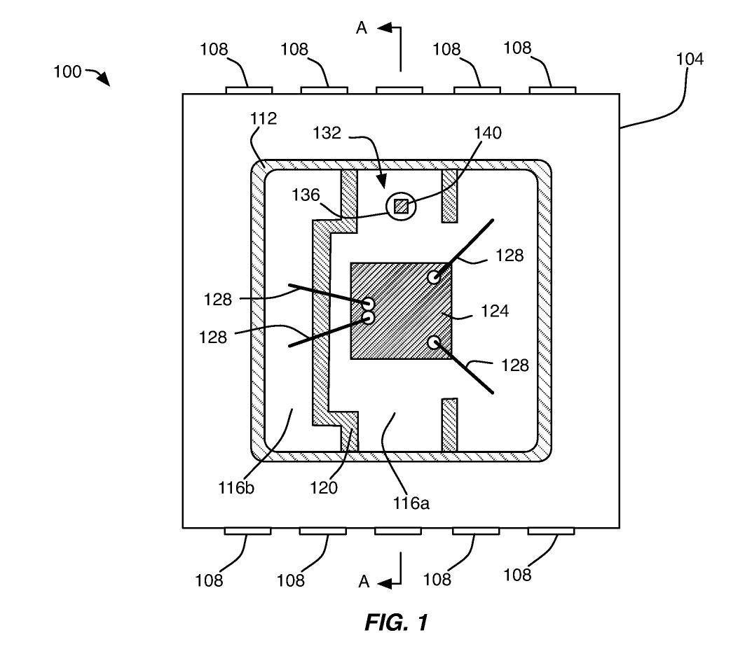

With reference now to FIGS. 1-3, a lighting package 100 and various possible configurations thereof will be described in accordance with at least some embodiments of the present disclosure. The lighting package 100 may comprise a lead frame and a plastic housing 104 that surrounds the lead frame. The lead frame may comprise a plurality of leads 108 and the lead frame may be divided into two or more sections, such as a first section 116a and second section 116b. Each section 116a, 116b may be separated by one or more isolation gaps 120 that correspond to a break in the lead frame where electrical current is prohibited from flowing.

The leads 108 may be provided to supply electrical current to one or more light sources 124 mounted thereto. In some embodiments, the light source 124 may be mounted within a reflector cup 112 which is a depression in the housing 104 configured to house the one or more light sources 124. In some embodiments, the reflective cup 112 may be filled with an encapsulant material to help direct or condition light emitted by the light source 124.

In some embodiments, the housing 104 is made of a plastic material, such as Polyphthalamide (PPA). Of course, the housing 104 may be made of other types of materials such as any other type of polymer or combination of polymers. In some embodiments, the housing 104 may be constructed of any polymer or combination of polymers using extrusion, machining, micro-machining, molding, injection molding, or a combination of such manufacturing techniques. In still other embodiments, the housing 104 may be constructed of other materials such as metal, ceramics, etc. In still other embodiments, the lighting package 100 may not have a housing 104 and rather may comprise a bare PCB onto which a light source 124 is mounted.

In the depicted examples, the leads 108 of the lead frame are exposed at the bottom of the reflector cup 112. The leads 108 may then extend or pass through part of the housing 104 to an outer surface (e.g., side surface(s) and/or bottom surface) of the housing 104, thereby facilitating attachment of the lighting package 100 to an electrical circuit (e.g., bonding pads on a Printed Circuit Board (PCB)). Although the leads 108 of the lead frame extending to the outer surface of the housing 104 are depicted a C-leads, embodiments of the present disclosure are not so limited. In particular, any other type or shape of leads may be utilized such as, for example, SOJ leads, gull wing leads, reverse gull wing leads, and straight cut leads.

The reflector cup 112 may be formed as a depression in a top portion of the housing 104. In some embodiments, the interior cylindrical (or conical) surface of the reflector cup 112 partially comprises the material of the housing 104 (e.g., plastic) and partially comprises the material of the lead frame (e.g., metal). In other embodiments, the entirety of the reflector cup 112 may comprise the material of the housing 104 and it may or may not be treated or covered with a reflective material such as gold, silver, aluminum, white paint, etc.

The material selected for the housing 104 may also be selected from any number of light or dark plastics or other non-conductive materials. In particular, the housing 104 may comprise a black or dark colored plastic that increases the contrast of the lighting package 100. Alternatively or additionally, some or all of the housing 104 may be constructed of a white or light colored plastic.

The light source(s) 124 in some embodiments, comprises a single LED, a plurality of LEDs, or an array of LEDs. Although the depicted embodiments only depict a single light source 124, it should be appreciated that a lighting package 100 may be equipped with multiple light sources without departing from the scope of the present disclosure. Specifically, the lighting package 100 may comprise one, two, three, four, five, . . . , ten, or more light sources 124. In a particular, but non-limiting embodiment, the lighting package 100 may comprise three light sources 124, where each light source emits light of a different color (e.g., Red, Green, and Blue). In other embodiments, multiple light sources 124 may be configured to emit light of the same or substantially the same color.

Each light source 124 may be connected to a different lead 108; accordingly, the lead frame may comprise any number of leads, depending upon the number of light sources 124 contained therein. In some embodiments, the lighting package 100 may comprise two, three, four, five, . . . , ten, twenty, or more leads 108. A single light source 124 may be connected to one or more different leads 108 via bonding wires 128.

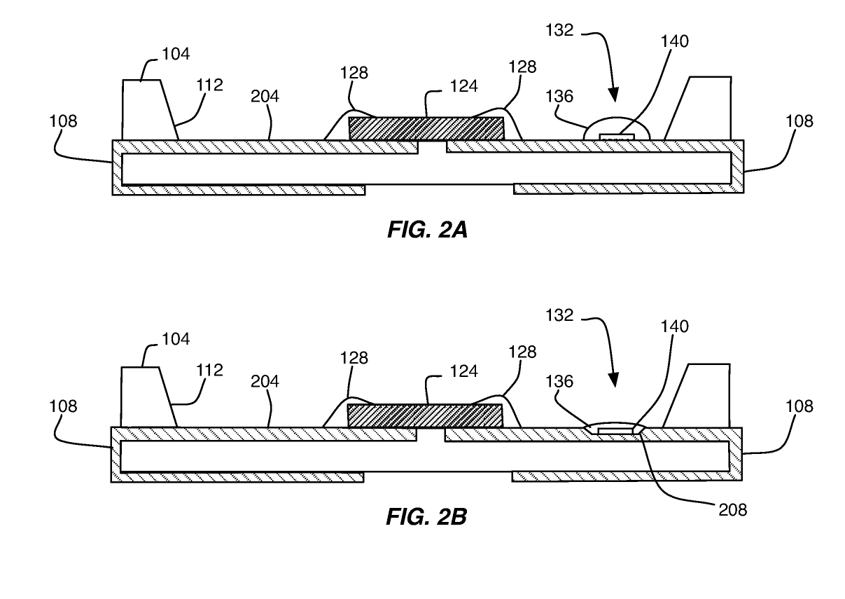

In some embodiments, the lead frame may be configured to carry current to the light source(s) 124 and more specifically each lead 108 may be configured to carry electrical current to or from a light source 124. As can be seen in FIGS. 2A and 2B, upper surfaces 204 of the lead frame sections 116a, 116b may be exposed in the bottom of the reflector cup 112. The bonding wires 128 may provide an electrical connection between the upper surface of the light source 124 and the leads 108.

In some embodiments, the light source(s) 124 may correspond to a Light Emitting Diode (LED), an array of LEDs, a laser diode, an array of laser diodes, or combinations thereof. As can be appreciated other non-light-emitting devices may also be mounted on the lead frame and may be connected thereto via one or more wires 128. Where an LED or similar light source is used, the one or more bonding wires 128 may be used to connect each light source 124 to the different portions of the lead frame. One surface of the light source 124 may correspond to an anode of the light source 124 and another surface of the light source 124 may correspond to a cathode of the light source 124. In such an embodiment, the bottom surface of the light source 124 may be directly connected to the lead frame without the need for a wire 128 whereas the top surface of the light source 124 may be electrically connected to the lead frame via a wire 128. Alternatively, as displayed in FIGS. 2A and 2B, both the anode and cathode may be on the same surface (e.g., the top surface) of the light source 124.

By connecting the light source 124 to two different sections 116a, 116b of the lead frame, an electrical potential can be applied across the anode and cathode of the light source 124 thereby energizing the light source 124 and causing it to emit light. A light source 124 comprising both an anode and cathode on a common surface may be constructed using known flip-chip manufacturing processes or any other known method for establishing both an anode and cathode on a common side of a light source 124. In such an embodiment, multiple bonding wires 128 may be used to connect to the anode and cathode separately to the first section 116a and the second section 116b of the lead.

In some embodiments, the light source(s) 124 is configured to emit light from its top surface. Light emitted by the light source(s) 124 may be coherent or incoherent in nature. In some embodiments, incoherent light is emitted by the light source(s) 124 and is scattered within the reflector cup 112. The emitted light may reflect off the interior walls of the reflector cup 112 that rise above the light source(s) 124.

In some embodiments, the interior walls of the reflector cup 112 may comprise both the lead frame and the housing 104 material. Stated another way, the reflector cup 112 may be treated with a reflective material that enables the reflector cup 112 to efficiently reflect light emitted by the light source 124.

In some embodiments, the lighting package 100 further comprises a mounted component 132 including an additional electrical component 140 that is at least partially covered with a cover material 136. In some embodiments, the additional electrical component 140 corresponds to an electrical component configured to protect the light source 124 and other components on the lighting package 100 from electrostatic discharge and other sources of voltage spikes that could otherwise damage such components. Even more specifically, the additional electrical component 140 may correspond to a Zener diode that is electrically connected to the lead frame via one or more of bonding wires, solder pads, or combinations thereof. As can be appreciated, other types of voltage/current spike protection devices can also be used as the additional electrical component, such as a TVS, for example. The additional electrical component 140 may be inherently constructed of a black or light-absorbing material that, without the addition of cover material 136 may degrade the optical performance of the lighting device 100. In some embodiments, the additional electrical component 140 may be electrically connected to the lead frame in a similar manner to that discussed above in connection with the light source 124.

Although only a single additional electrical component 140 is depicted as being included in the lighting package 100 it should be appreciated that embodiments of the present disclosure are not so limited. Specifically, the lighting package 100 may comprise one, two, three, four, five, . . . , ten, or more additional electrical components 140 and some or all of the additional electrical components may be covered with a cover material 136 to help improve the optical reflectivity of the additional electrical component 140.

In some embodiments, a separate additional electrical component 140 may be provided for each light source 124. For instance, if the lighting package 100 comprises three light sources 124, then the lighting package 100 may also comprise three additional electrical components 140, each being configured to protect a different one of the light sources 124. In some embodiments, the multiple additional electrical components 140 may be covered by separate cover materials 136 or a common cover material 136. Where separate cover materials 136 are used for each additional electrical component 140, the separate cover materials 136 may be the same or different (e.g., different types of materials may be used to cover different additional electrical components 140).

In some embodiments, the type of material used as the cover material 136 may correspond to any type of material that is electrically insulative and reflective. More specific examples of materials that may be used for the cover material 136 include, without limitation, TiO2, Alumina in epoxy, and/or a silicone adhesive material. The cover material 136 may be white or any other reflective color that helps enhance the overall reflectivity of the additional electrical component 140.

As can be seen in FIGS. 2A and 2B, the additional electrical component 140 may be mounted on the upper surface 204 of the lead frame similar to the light source 124. In the configuration of FIG. 2A, the upper surface 204 of the lead frame is depicted as being generally planar and the bottom surface of the additional electrical component 140 is substantially co-planar with the bottom surface of the light source 124. In the configuration of FIG. 2B, the upper surface 204 of the lead frame comprises at least one recess or depression 208 in which the additional electrical component 140 is mounted. By mounting the additional electrical component 140 in the recess or depression 208, the amount of cover material 136 required to cover the additional electrical component 140 can be decreased. Moreover, by providing the additional electrical component 140 in the recess or depression 208, the amount of additional electrical component 140 exposed to light emitted by the additional light source 124 can be minimized.

It should be appreciated that in some embodiments, the cover material 136 may be optional. More specifically, if the optical performance of the lighting package 100 is satisfactory when the additional electrical component 140 is mounted in the recess or depression 208, then the need for an additional step of depositing the cover material 136 may be obviated.

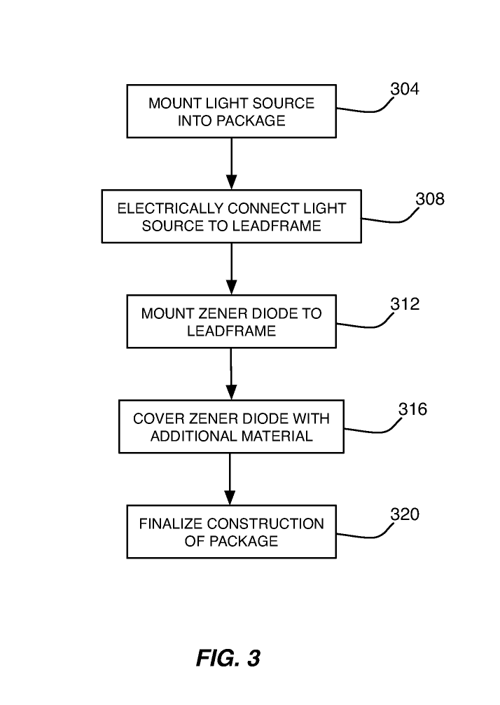

With reference now to FIG. 3, a method of constructing a lighting package 100 will be described in accordance with at least some embodiments of the present disclosure. The method begins by mounting one or more light sources 124 into a lighting package 100 (step 304). In some embodiments, this particular step may comprise surface mounting the light source 124 onto an upper surface 204 of a lead frame of the lighting package 100. More specifically, while embodiments of the present disclosure contemplate the use of thru-hole light sources, a lower-profile lighting package 100 can be achieved by utilizing a surface mount light source 124 that has its bottom surface mounted onto the upper surface 204 of the lead frame. As discussed above, this step may also inherently establish an electrical connection between the light source 124 and lead frame where the light source 124 has one of its anode and cathode on its bottom surface.

After the light source 124, or multiple light sources, has been mounted onto the lead frame, the method continues by electrically connecting the light source to the lead frame (step 308). In some embodiments, this may include connecting one or more bonding wires 128 between the light source 124 and a lead 108 of the lead frame. As noted above, some or all of step 308 may be performed concurrently with step 304.

Before, during, or after the light source 124 has been mounted to the lead frame, the additional electrical component(s) 140 may be mounted to the lead frame (step 312). In some embodiments, the additional electrical component 140 correspond to a Zener diode and the Zener diode is mounted in proximity to the light source 124. Even more specifically, the Zener diode 140 may be mounted on the upper surface 204 of the lead frame and it may or may not be mounted in a recess or depression 208 established on the upper surface 204 of the lead frame.

As with the light source 124, the additional electrical component 140 may also be electrically connected to the lead frame. This step may occur during or after step 312. Thereafter, the method continues by covering the additional electrical component 140 with a cover material 136 (step 316). The cover material 136 may be delivered by one or more of dispensing, spraying, screen printing, deposition, molding, or combinations thereof

The method continues by finalizing the construction of the lighting package 100 (step 320). Specifically, any additional finishing steps (e.g., lead forming 108, lead 108 trimming, depositing an encapsulant in the reflector cup 112, singulation, etc.). The step of singulation may occur where batch production of the lighting packages 100 are being employed. Specifically, a plurality of lighting packages 100 may be constructed substantially simultaneously on a common substrate or with a common lead frame sheet having a plurality of lead frames for multiple lighting packages 100. The step of singulation may comprise separating or cutting each individual lighting package 100 from the batch and preparing each lighting package 100 for sale, testing, and/or delivery to a customer.

Specific details were given in the description to provide a thorough understanding of the embodiments. However, it will be understood by one of ordinary skill in the art that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A lighting package, comprising:
a lead frame comprising an upper surface on which a light source and an additional electrical component are mounted, the additional electrical component corresponding to a device configured to protect the light source from at least one of current and voltage spikes;
a housing at least partially surrounding the light source and additional electrical component; and
a cover material at least partially covering the additional electrical component and being configured to reflect light emitted by the light source.

2. The package of claim 1, wherein the additional electrical component comprises a Zener diode.

3. The package of claim 1, wherein the upper surface of the lead frame comprises at least one of a recess and depression in which the additional electrical component is mounted.

4. The package of claim 1, wherein a bottom surface of the light source is substantially co-planar with a bottom surface of the additional electrical component.

5. The package of claim 4, wherein at least one of the light source and additional electrical component are mounted to the lead frame via at least one solder pad.

6. The package of claim 1, wherein at least one bonding wire is used to electrically connect the light source to a lead of the lead frame.

7. The package of claim 1, wherein the cover material completely covers the additional electrical component.

8. The package of claim 1, wherein the cover material comprises at least one of TiO2, Alumina in epoxy, and a silicone adhesive material.

9. The package of claim 1, wherein the housing comprises a reflector cup that substantially surround the light source, the reflector cup comprising at least one reflective material.

10. The package of claim 1, wherein the light source comprises at least one of a Light Emitting Diode (LED), and array of LEDs, a laser diode, and an array of laser diodes.

11. A PLCC package, comprising:
a plastic housing; and
a lead frame comprising an upper surface on which a light source and a Zener diode are mounted, the lead frame having the plastic housing mounted thereto, the Zener diode being at least one of covered and hidden such that light emitted by the light source is not substantially absorbed by the Zener diode.

12. The PLCC package of claim 11, wherein less than 3% of optical losses are due to the Zener diode.

13. The PLCC package of claim 11, wherein the Zener diode is at least partially covered with a cover material.

14. The PLCC package of claim 13, wherein the cover material comprises at least one of TiO2, Alumina in epoxy, and a silicone adhesive material.

15. The PLCC package of claim 11, wherein the Zener diode is mounted in at least one of a recess and depression established on the upper surface of the lead frame such that a bottom surface of the Zener diode is not co-planar with a bottom surface of the light source.

16. The PLCC package of claim 15, wherein the at least one of a recess and depression are further filled with a cover material that is more reflective as compared to the Zener diode.

17. The PLCC package of claim 11, wherein the lead frame comprises at least a first and second lead that are formed as at least one of C-leads, SOJ leads, gull wing leads, reverse gull wing leads, and straight cut leads.

18. A method of manufacturing a lighting package, comprising:
mounting a light source on an upper surface of a lead frame of the lighting package;
electrically connecting the light source to the lead frame;
mounting a circuit protection device on the upper surface of the lead frame;
electrically connecting the circuit protection device to the lead frame so as to provide electrostatic discharge protection to the light source; and
performing at least one of the following:
mounting the circuit protection device in at least one of a recess and depression established on the upper surface of the lead frame; and
covering the circuit protection device with a cover material that is configured to reflect light emitted by the light source.

19. The method of claim 18, wherein the circuit protection device is both mounted in the at least one of a recess and depression and covered with the cover material.

20. The method of claim 18, wherein the circuit protection device is covered with the cover material and wherein the cover material comprises at least one of TiO2, Alumina in epoxy, and a silicone adhesive material.
